(19) United States
(12) Patent Application Publication
(10) Pub. No.: US 2026/0104964 A1
(43) Pub. Date: Apr. 16, 2026

(54) MEMORY SYSTEM AND ERROR CORRECTION METHOD THEREOF

(71) Applicant: SK hynix Inc., Gyeonggi-do (KR)

(72) Inventor: Jae Il LIM, Gyeonggi-do (KR)

(21) Appl. No.: 19/209,738

(22) Filed: May 15, 2025

(30) Foreign Application Priority Data
Oct. 16, 2024 (KR) 10- 2024-0141095

(51) Int. Cl. G06F 11/10

(52) U.S. Cl. CPC G06F 11/1068; G06F 11/1004; G06F 11/1048

(57) ABSTRACT

An error correction method on a plurality of memory devices, the method comprising: an error check operation of generating an error sum data piece by performing a parity check operation on a plurality of data pieces from the respective memory devices, a test preparation operation of generating a third data piece by performing a parity check operation between the error sum data piece and a second data piece from a target memory device, to generate test data by replacing the second data piece with the third data piece, an error correction operation of generating a correction data piece by correcting an error in the test data, a judgment operation of judging whether a miscorrection has occurred in the correction data piece when the error correction operation is successful, and a determination operation of determining whether the error correction method is successful according to results of the judgment operation.

### CROSS-REFERENCE TO RELATED APPLICATION

This application claims priority under 35 U.S.C. § 119(a) to Korean Patent Application No. 10-2024-0141095, filed on Oct. 16, 2024, the entire contents of which are incorporated herein by reference.

### BACKGROUND

### 1. Field

Embodiments of the present disclosure relate to a memory system, and particularly, to a memory system including a plurality of memory devices and an error correction device, and an error correction method of the memory system.

### 2. Discussion of the Related Art

Memory systems are storage devices embodied using a semiconductor such as silicon (Si), germanium (Ge), gallium arsenide (GaAs), indium phosphide (InP), or the like. The memory systems are classified into a volatile memory device and a nonvolatile memory device. The volatile memory device is a memory device in which data stored therein is lost when power supply is interrupted. Representative examples of the volatile memory device include static RAM (SRAM), dynamic RAM (DRAM), synchronous DRAM (SDRAM), etc. The nonvolatile memory device is a memory device in which data stored therein is retained even when power supply is interrupted. Representative examples of the nonvolatile memory device include a read only memory (ROM), a programmable ROM (PROM), an electrically programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), etc. Flash memories are chiefly classified into a NOR-type memory and NAND-type memory.

On the other hand, a semiconductor memory is being widely used for various computing systems, and as computing technology is developed, demands for large capacity of memories are increasing. In order to satisfy such demands, a plurality of memory devices is currently provided in the form of a memory module such as a dual in-line memory module (DIMM).

In the memory device, an error may occur in bit data stored therein due to physical damage or the like. To restore such damaged data, an error correction code (hereinafter, referred to as ECC) is mainly used. In particular, a single device data correction (SDDC) error may occur, which is a phenomenon in which an error intensively occurs in a specific memory device among a plurality of memory devices provided in the form of a memory module. To correct such a SDDC error, an attempt has been made to directly put a separate ECC into the memory module. However, directly putting the ECC into the memory module may cause issues such as increasing the production cost of the memory module and increasing the operation latency of the memory module.

### SUMMARY

Various embodiments of the present disclosure are directed to providing a memory system that can effectively detect and correct a single device data correction (SDDC) error indicating a phenomenon in which an error intensively occurs in a specific memory device among a plurality of memory devices, and an error correction method of the memory system.

Technical problems to be solved by the present disclosure are not limited to the aforementioned technical problems and other unmentioned technical problems will be clearly understood by those skilled in the art from the following description.

According to an embodiment of the present disclosure, an error correction method of a memory system comprising a plurality of memory devices each storing data and an error correction code, the method may include: an error check operation of generating an error sum data piece by performing a parity check operation on a plurality of first data pieces read from the respective memory devices by using the error correction code; a test preparation operation of generating, according to a result of the error check operation, a third data piece by performing a parity check operation between the error sum data piece and a second data piece, which is one among the plurality of first data pieces and read from a target memory device selected from among the plurality of memory devices, to generate test data by replacing the second data piece with the third data piece; an error correction operation of generating a correction data piece by correcting an error in the test data by using the error correction code; a judgment operation of judging whether a miscorrection has occurred in the correction data piece when the error correction operation is successful; and a determination operation of determining, as a result of repeating the test preparation operation, the error correction operation and the judgement operation on the respective first data pieces, whether the error correction method is successful or failed according to a number of times the judgment operation is performed and results of the judgment operation.

According to an embodiment of the present disclosure, a memory system may include: a plurality of memory devices each configured to store data and an error correction code; and an error correction device configured to perform an error correction method including: an error check operation of generating error sum data piece by performing a parity check operation on a plurality of first data pieces read from the respective memory devices by using the error correction code, a test preparation operation of generating, according to a result of the error check operation, third data piece by performing a parity check operation between the error sum data piece and second data piece, which is one among the plurality of first data pieces and read from a target memory device selected from among the plurality of memory devices, to generate test data by replacing the second data piece with the third data piece, an error correction operation of generating a correction data piece by correcting an error in the test data by using the error correction code, a judgment operation of judging whether a miscorrection has occurred in the correction data piece when the error correction operation is successful, and a determination operation of determining, as a result of repeating the test preparation operation, the error correction operation and the judgement operation on the respective first data pieces, whether the error correction method is successful or failed according to a number of times the judgment operation is performed and results of the judgment operation.

According to the present disclosure, in a memory system including a plurality of memory devices, by appropriately adjusting a use time point and a use method of an error detection operation, such as a parity check operation and a cyclic redundancy check (CRC), and an error correction operation, such as a Bose-Chaudhuri-Hocquenghem (BCH) code and a Reed-Solomon (RS) code, on data read from the plurality of memory devices, it is possible to effectively detect a single device data correction (SDDC) error indicating a phenomenon in which an error intensively occurs in a specific memory device among the plurality of memory devices and to efficiently correct the detected SDDC error.

### BRIEF DESCRIPTION OF THE DRAWINGS

FIG. 1 is a diagram for describing a memory system that performs an error correction process in accordance with an embodiment of the present disclosure.

FIG. 2 is a diagram for describing data read from a plurality of memory devices included in the memory system in accordance with an embodiment of the present disclosure.

FIG. 3 is a diagram for describing an error check operation in the error correction process performed by the memory system in accordance with an embodiment of the present disclosure.

FIGS. 4A and 4B are diagrams for describing a test preparation operation and an error correction operation in the error correction process performed by the memory system in accordance with an embodiment of the present disclosure.

FIGS. 5A and 5B are diagrams for describing another test preparation operation and error correction operation in the error correction process performed by the memory system in accordance with an embodiment of the present disclosure.

FIGS. 6A to 6D are flowcharts illustrating the order of the error correction process performed by the memory system in accordance with an embodiment of the present disclosure.

FIGS. 7A and 7B are diagrams illustrating an embodiment of an extended memory system including the memory system described in FIG. 1.

### DETAILED DESCRIPTION

Various embodiments of the present disclosure are described below with reference to the accompanying drawings. Elements and features of this disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components (e.g., an interface unit, circuitry, etc.).

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational (e.g., is not turned on nor activated). The block/unit/circuit/component used with the “configured to” language includes hardware-, for example, circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that implement or perform one or more tasks.

As used in this disclosure, the term ‘circuitry’ or ‘logic’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘circuitry’ or ‘logic’ applies to all uses of this term in this application, including in any claims. As a further example, as used in this application, the term “circuitry” or “logic” also covers an implementation of merely a processor (or multiple processors) or a portion of a processor and its (or their) accompanying software and/or firmware. The term “circuitry” or “logic” also covers, for example, and if applicable to a particular claim element, an integrated circuit for a storage device.

As used herein, the terms “first,” “second,” “third,” and so on are used as labels for nouns that the terms precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise has the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. For example, the phrase “determine A based on B.” While in this case, B is a factor that affects the determination of A, such a phrase does not foreclose the determination of A from also being based on C. In other instances, A may be determined based solely on B.

Herein, an item of data, a data item, a data entry or an entry of data may be a sequence of bits. For example, the data item may include the contents of a file, a portion of the file, a page in memory, an object in an object-oriented program, a digital message, a digital scanned image, a part of a video or audio signal, metadata or any other entity which can be represented by a sequence of bits. According to an embodiment, the data item may include a discrete object. According to another embodiment, the data item may include a unit of information within a transmission packet between two different components.

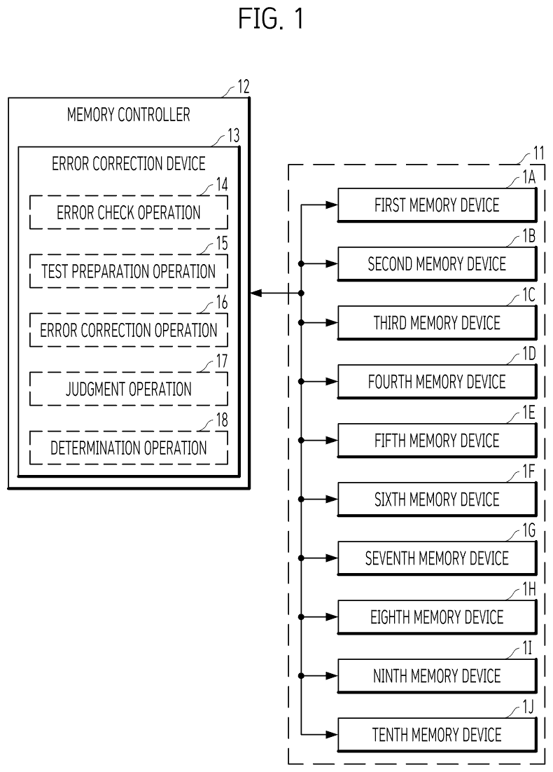

FIG. 1 is a diagram for describing a memory system that performs an error correction process in accordance with an embodiment of the present disclosure.

Referring to FIG. 1, the memory system in accordance with the embodiment of the present disclosure includes a memory module 11 and a memory controller 12. In addition, the memory controller 12 may include an error correction device 13.

The memory module 11 includes a plurality of memory devices 1<A:J>. In such a case, data and an error correction code (not illustrated) is stored in the plurality of memory devices 1<A:J>.

According to an embodiment, each of the plurality of memory devices 1<A:J> included in the memory module 11 is a volatile memory device such as a static RAM (SRAM), a dynamic RAM (DRAM), or a synchronous DRAM (SDRAM).

According to another embodiment, each of the plurality of memory devices 1<A:J> included in the memory module 11 is a nonvolatile memory device such as a read only memory (ROM), a programmable ROM (PROM), an electrically programmable ROM (EPROM), an electrically erasable and programmable ROM (EEPROM), a flash memory device, a phase-change RAM (PRAM), a magnetic RAM (MRAM), a resistive RAM (RRAM), and a ferroelectric RAM (FRAM).

The memory controller 12 controls the operation of the memory module 11, that is, the operation of each of the plurality of memory devices 1<A:J>.

According to an embodiment, when each of the plurality of memory devices 1<A:J> is a volatile memory device, the memory controller 12 controls a write operation of storing data input from the outside in the plurality of memory devices 1<A:J> and a read operation of reading data stored in the plurality of memory devices 1<A:J>.

According to another embodiment, when each of the plurality of memory devices 1<A:J> is a nonvolatile memory device, the memory controller 12 further controls, in addition to the write operation and the read operation, an erase operation of deleting data stored in the plurality of memory devices 1<A:J> and an operation of moving or copying data between the plurality of memory devices 1<A:J>.

In addition, the error correction device 13 included in the memory controller 12 performs an error correction process on data transmitted between the memory controller 12 and the memory module 11.

Specifically, the error correction device 13 includes an error correction encoder (not illustrated) and an error correction decoder (not illustrated). The error correction encoder encodes data input from the outside during a write operation to generate an error correction code, thereby allowing the error correction code to be stored in the plurality of memory devices 1<A:J> together with the data input from the outside. The error correction code generated by the error correction encoder in accordance with the embodiment of the present disclosure is a product code formed by multiplying a polynomial (Generator polynominal) generated in response to any of a Bose-Chaudhuri-Hocquenghem (BCH) code and a Reed Solomon (RS) code, a polynomial generated in response to a code for parity check, and a polynomial generated in response to a code for cyclic redundancy check (CRC) together. That is, the encoding operation performed by the error correction encoder in accordance with the embodiment of the present disclosure is the same as an operation of performing an encoding operation using any of the Bose-Chaudhuri-Hocquenghem (BCH) code and the Reed-Solomon (RS) code, an encoding operation using a code for parity check, and an encoding operation using a code for cyclic redundancy check (CRC). The method of generating a new code by multiplying a plurality of polynomials is a known technology and is not described in detail here.

In addition, the error correction decoder performs an error correction process on data read from the plurality of memory devices 1<A:J> during a read operation. In such a case, the error correction device 13 in accordance with the embodiment of the present disclosure performs an error correction process including an error check operation 14, a test preparation operation 15, an error correction operation 16, a judgment operation 17, and a determination operation 18. In the error correction decoder, a decoding operation using any of the Bose-Chaudhuri-Hocquenghem (BCH) code and the Reed Solomon (RS) code, a decoding operation using a code for parity check, and a decoding operation using a code for cyclic redundancy check (CRC) is further performed in the error check operation 14 and the error correction operation 16.

The error correction decoder may check and correct errors in data transmitted between the controller 130 and the memory device 1<A:J> or 150. The error correction unit 138 may be implemented as a separate module, circuit or firmware in the controller 130, but also be implemented in the memory device 1<A:J> or 150 according to an embodiment.

The error correction decoder may include all circuits, modules, systems, and/or devices for performing the error correction operation based on at least one of the above-described codes.

More specifically, the error check operation 14 performed by the error correction device 13 is an operation of generating an error sum data piece (not illustrated) by performing a parity check operation on a plurality of first data pieces (not illustrated) read from the respective memory devices 1<A:J> using the error correction code stored in the plurality of memory devices 1<A:J>.

In addition, the test preparation operation 15 performed by the error correction device 13 is an operation of generating, according to a result of the error check operation 14, a third data piece (not illustrated) by performing a parity check operation between the error sum data piece and a second data piece (not illustrated), which is one among the plurality of first data pieces and read from any target memory device among the plurality of memory devices 1<A:J>, and then generating test data (not illustrated) by replacing the second data piece with the third data piece.

In addition, the error correction operation 16 performed by the error correction device 13 is an operation of generating a correction data piece (not illustrated) by correcting an error in the test data using the error correction code stored in the plurality of memory devices 1<A:J>.

In addition, the judgment operation 17 performed by the error correction device 13 is an operation of judging whether a miscorrection has occurred in the correction data piece when the error correction operation 16 is successful.

In addition, the determination operation 18 performed by the error correction device 13 is an operation of determining whether the error correction process is successful or failed based on the number of times the judgment operation 17 is performed and results of performing the judgment operation 17 as a result that each of repeating the test preparation operation 15, the error correction operation 16 and the judgment operation 17 on the respective first data pieces corresponding to the plurality of memory devices 1<A:J>.

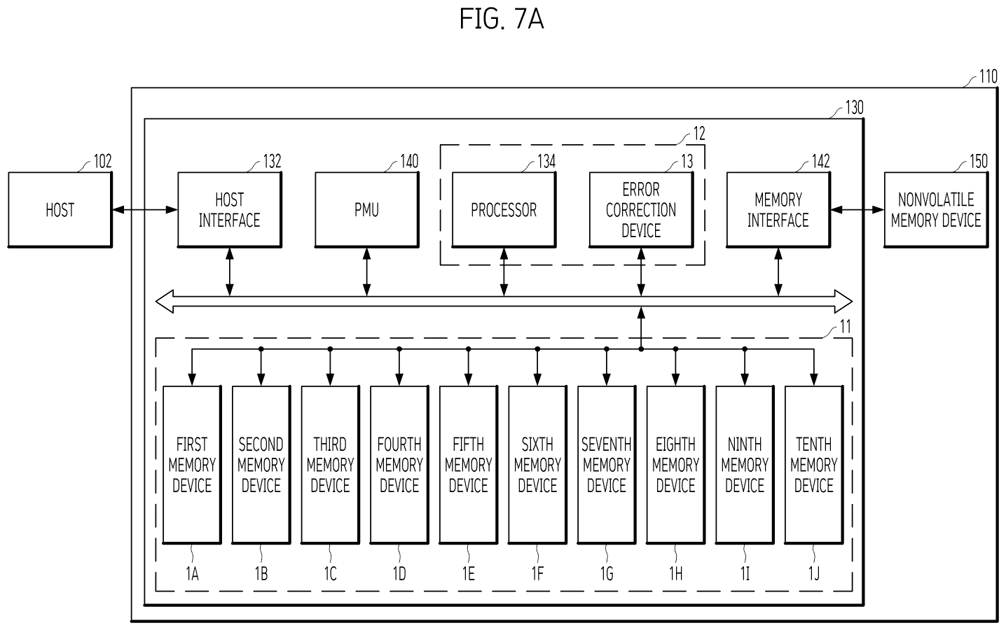

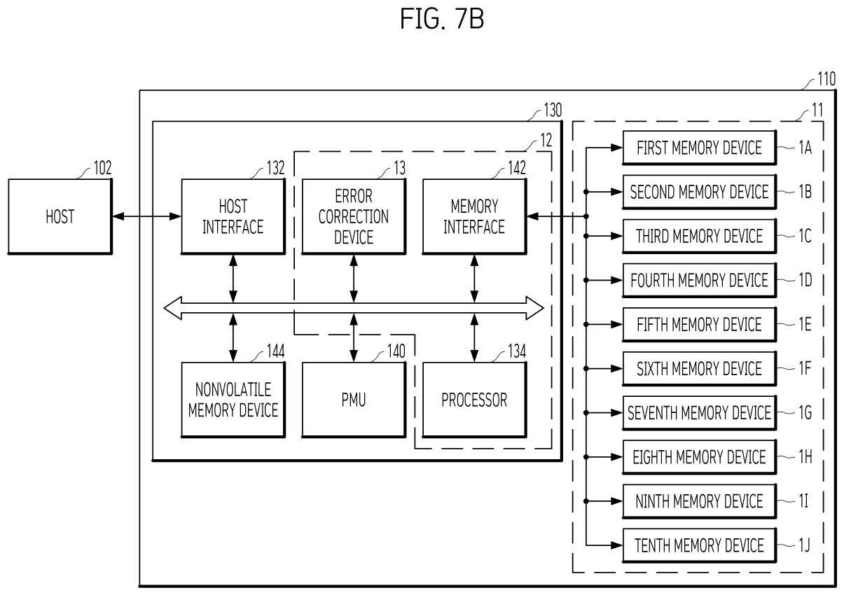

On the other hand, referring to FIGS. 7A and 7B together with FIG. 1, the memory controller 12 and the plurality of memory devices 1<A:J> illustrated in FIG. 1 are some components of the memory system 110 illustrated in FIGS. 7A and 7B. That is, the memory controller 12 illustrated in FIG. 1 refers to a component for performing an error correction process on data transmitted between the memory controller 12 and the plurality of memory devices 1<A:J> among various components included in the controller 130 of the memory system 110 illustrated in FIGS. 7A and 7B. Accordingly, it can be seen that the reference numerals 11 to 13 of the components illustrated in FIG. 1 are identically included in FIGS. 7A and 7B.

Specifically, the memory system 110 includes a memory device 150 or 1<A:J> and a controller 130.

The memory device 150 or 1<A:J> and the controller 130 are physically distinct components. In addition, the memory device 150 or 1<A:J> and the controller 130 are functionally distinct components. In addition, the memory device 150 or 1<A:J> and the controller 130 are connected by at least one data path. For example, the data path is constituted by a channel and/or a way. In addition, the memory device 150 or 1<A:J> and the controller 130 are implemented through one semiconductor device chip or a plurality of semiconductor device chips. In the case of the memory system 110 requiring high integration, the memory device 150 or 1<A:J> and the controller 130 are constituted by one semiconductor device chip.

The controller 130 controls the memory device 150 or 1<A:J> to perform operations such as read, program/write, and erase in response to a request from the host 102. In addition, the controller 130 controls the memory device 150 or 1<A:J> to independently operate the memory system 110 regardless of a request from the host 102.

According to the embodiment, FIG. 7A illustrates that a memory device functionally distinguished from the controller 130 of the memory system 110 is a nonvolatile memory device 150. That is, FIG. 7A shows that the plurality of memory devices 1<A:J> are included in the controller 130 based on that the plurality of memory devices 1<A:J> described with reference to FIG. 1 are operating memories used for the control operation of the controller 130. Each of the plurality of memory devices 1<A:J> is a volatile memory device or a nonvolatile memory device.

In such a case, among the components included in the controller 130 illustrated in FIG. 7A, a processor 134 and the error correction device 13 are components distinguished from the memory controller 12 described with reference to FIG. 1. Accordingly, in the memory system 110 having the structure illustrated in FIG. 7A, the error correction device 13 performs an error correction process on data transmitted between the error correction device 13 and each of the plurality of memory devices 1<A:J> through a data bus.

According to another embodiment, FIG. 7B illustrates that the memory device functionally distinguished from the controller 130 of the memory system 110 is the plurality of memory devices 1<A:J> described with reference to FIG. 1. That is, FIG. 7B shows that the plurality of memory devices 1<A:J> are provided outside the controller 12 based on that the plurality of memory devices 1<A:J> described with reference to FIG. 1 are memories operating under the control of the controller 12. Each of the plurality of memory devices 1<A:J> is a volatile memory device or a nonvolatile memory device.

In such a case, among the components included in the controller 130 illustrated in FIG. 7B, the processor 134, the error correction device 13, and the memory interface 142 are components distinguished from the memory controller 12 described with reference to FIG. 1. Accordingly, in the memory system 110 having the structure illustrated in FIG. 7B, the error correction device 13 performs an error correction process on data transmitted between the error correction device 13 and each of the plurality of memory devices 1<A:J> through a data path, that is, data transmitted through a channel or a way.

According to an embodiment, when each of the plurality of memory devices 1<A:J> is a volatile memory device, the controller 12 illustrated in FIG. 7B does not include a volatile memory device 144 used as an operating memory internally, or includes a volatile memory device that operates at a higher speed than the plurality of memory devices 1<A:J> even though the controller 12 includes the volatile memory device 144.

According to another embodiment, when each of the plurality of memory devices 1<A:J> is a nonvolatile memory device, the controller 12 illustrated in FIG. 7B includes the volatile memory device 144 used as an operating memory internally.

According to still another embodiment, the memory system 110 illustrated in FIGS. 7A and 7B is connected to the host 102 via a compute express link (CXL) interface. The CXL interface is an interface based on peripheral component interconnect express (PCIe), and is an interface designed to enable a central processing unit (CPU), a graphics processing unit (GPU), and various types of accelerators to more efficiently use a memory or the like. That is, the memory system 110 illustrated in FIGS. 7A and 7B increases the memory capacity of a computer system such as a data center or a server by connecting the memory system 110 to the host 102 through the CXL interface, and enables various processors within the computer system to share a memory.

More specifically, the controller 130 in accordance with the embodiment of the present disclosure includes a host interface 132, the processor 134, a power management unit (PMU) 140, and the memory interface 142 together with the error correction device 13. The controller 130 further includes the plurality of memory devices 1<A:J> or the volatile memory device 144 as an internal operating memory.

The host 102 and the memory system 110 each may include a controller or an interface for transmitting and receiving signals, data, and the like, in accordance with one or more predetermined protocols. For example, the host interface 132 in the memory system 110 may include an apparatus capable of transmitting signals, data, and the like to the host 102 or receiving signals, data, and the like from the host 102.

The host interface 132 included in the controller 130 may receive signals, commands (or requests), and/or data input from the host 102 via a bus. For example, the host 102 and the memory system 110 may use a predetermined set of rules or procedures for data communication or a preset interface to transmit and receive data therebetween.

Examples of communication standards or interfaces used to transmit/receive data may include various form factors such as 2.5-inch form factor, 1.8-inch form factor, MO-297, MO-300, M.2, and EDSFF (Enterprise and Data Center SSD Form Factor) and various communication standards or interfaces such as USB (Universal Serial Bus), MMC (Multi-Media Card), PATA (Parallel Advanced Technology Attachment), SCSI (Small Computer System Interface), ESDI (Enhanced Small Disk Interface), IDE (Integrated Drive Electronics), PCIe (Peripheral Component Interconnect Express), SAS (Serial-attached SCSI), SATA (Serial Advanced Technology Attachment), and MIPI (Mobile Industry Processor Interface).

According to an embodiment, the host interface 132 is a type of layer for exchanging data with the host 102 and is implemented with, or driven by, firmware called a host interface layer (HIL). According to an embodiment, the host interface 132 can include a command queue.

The Integrated Drive Electronics (IDE) or Advanced Technology Attachment (ATA) may be used as one of the interfaces for transmitting and receiving data and, for example, may use a cable including 40 wires connected in parallel to support data transmission and data reception between the host 102 and the memory system 110. When a plurality of memory systems 110 are connected to a single host 102, the plurality of memory systems 110 may be divided into a master and a slave by using a position or a dip switch to which the plurality of memory systems 110 are connected. The memory system 110 set as the master may be used as a main memory device. The IDE (ATA) may include, for example, Fast-ATA, ATAPI, or Enhanced IDE (EIDE).

A Serial Advanced Technology Attachment (SATA) interface is a type of serial data communication interface that is compatible with various ATA standards of parallel data communication interfaces which are used by Integrated Drive Electronics (IDE) devices. The 40 wires in the IDE interface can be reduced to six wires in the SATA interface. For example, 40 parallel signals for the IDE can be converted into 6 serial signals for the SATA interface. The SATA interface has been widely used because of its faster data transmission and reception rate and its less resource consumption in the host 102 used for the data transmission and reception. The SATA interface may connect up to 30 external devices to a single transceiver included in the host 102. In addition, the SATA interface can support hot plugging that allows an external device to be attached to or detached from the host 102, even while data communication between the host 102 and another device is being executed. Thus, the memory system 110 can be connected or disconnected as an additional device, like a device supported by a universal serial bus (USB) even when the host 102 is powered on. For example, in the host 102 having an eSATA port, the memory system 110 may be freely attached to or detached from the host 102 like an external hard disk.

Small Computer System Interface (SCSI) is a type of serial data communication interface used for connecting a computer or a server with other peripheral devices. The SCSI can provide a high transmission speed, as compared with other interfaces such as IDE and SATA. In the SCSI, the host 102 and at least one peripheral device (e.g., memory system 110) are connected in series, but data transmission and reception between the host 102 and each peripheral device may be performed through a parallel data communication. In the SCSI, it is easy to connect or disconnect a device such as the memory system 110 to or from the host 102. The SCSI can support connections of 15 other devices to a single transceiver included in host 102.

Serial Attached SCSI (SAS) can be understood as a serial data communication version of the SCSI. In the SAS, the host 102 and a plurality of peripheral devices are connected in series, and data transmission and reception between the host 102 and each peripheral device may be performed in a serial data communication scheme. The SAS can support connection between the host 102 and the peripheral device through a serial cable instead of a parallel cable, to easily manage equipment using the SAS and enhance or improve operational reliability and communication performance. The SAS may support connections of eight external devices to a single transceiver included in the host 102.

The Non-volatile memory express (NVMe) is a type of interface based at least on a Peripheral Component Interconnect Express (PCIe) designed to increase performance and design flexibility of the host 102, servers, computing devices, and the like equipped with the non-volatile memory system 110. The PCIe can use a slot or a specific cable for connecting a computing device (e.g., host 102) and a peripheral device (e.g., memory system 110). For example, the PCIe can use a plurality of pins (e.g., 18 pins, 32 pins, 49 pins, or 82 pins) and at least one wire (e.g., x1, x4, x8, or x16) to achieve high speed data communication over several hundred MB per second (e.g., 250 MB/s, 500 MB/s, 984.6250 MB/s, or 1969 MB/s). According to an embodiment, the PCIe scheme may achieve bandwidths of tens to hundreds of Giga bits per second. The NVMe can support an operation speed of the non-volatile memory system 110, such as an SSD, that is faster than a hard disk.

According to an embodiment, the host 102 and the memory system 110 may be connected through a universal serial bus (USB). The Universal Serial Bus (USB) is a type of scalable, hot-pluggable plug-and-play serial interface that can provide cost-effective standard connectivity between the host 102 and peripheral devices such as a keyboard, a mouse, a joystick, a printer, a scanner, a storage device, a modem, a video camera, and the like. A plurality of peripheral devices such as the memory system 110 may be coupled to a single transceiver included in the host 102.

In the case of the memory system 110 illustrated in FIG. 7A, the error correction device 13 performs an error correction process for the plurality of memory devices 1<A:J> included in the controller 130 as well as an error correction process for the nonvolatile memory device 150 provided outside the controller 130.

The power management unit (PMU) 140 may control electrical power provided to the controller 130. The PMU 140 may monitor the electrical power supplied to the memory system 110, e.g., a voltage supplied to the controller 130, and provide the electrical power to components included in the controller 130. The PMU 140 may not only detect power-on or power-off, but also generate a trigger signal to enable the memory system 110 to urgently back up a current state when the electrical power supplied to the memory system 110 is unstable. According to an embodiment, the PMU 140 may include a device or a component capable of accumulating electrical power that may be used in an emergency.

The memory interface 142 may serve as an interface for handling commands and data transferred between the controller 130 and the memory device 1<A:J> or 1<A:J> or 150, in order to allow the controller 130 to control the memory device 1<A:J> or 1<A:J> or 150 in response to a command or a request input from the host 102. The memory interface 142 may generate a control signal for the memory device 1<A:J> or 1<A:J> or 150 and may process data input to, or output from, the memory device 1<A:J> or 1<A:J> or 150 under the control of the processor 134 in a case when the memory device 1<A:J> or 1<A:J> or 150 is a flash memory.

For example, when the memory device 1<A:J> or 1<A:J> or 150 includes a NAND flash memory, the memory interface 142 includes a NAND flash controller (NFC). The memory interface 142 can provide an interface for handling commands and data between the controller 130 and the memory device 1<A:J> or 1<A:J> or 150. In accordance with an embodiment, the memory interface 142 can be implemented through, or driven by, firmware called a Flash Interface Layer (FIL) for exchanging data with the memory device 1<A:J> or 1<A:J> or 150.

According to an embodiment, the memory interface 142 may support an open NAND flash interface (ONFi), a toggle mode, or the like, for data input/output with the memory device 1<A:J> or 1<A:J> or 150. For example, the ONFi may use a data path (e.g., a channel, a way, etc.) that includes at least one signal line capable of supporting bi-directional transmission and reception in a unit of 8-bit or 16-bit data. Data communication between the controller 130 and the memory device 1<A:J> or 1<A:J> or 150 can be achieved through at least one interface regarding an asynchronous single data rate (SDR), a synchronous double data rate (DDR), a toggle double data rate (DDR), or the like.

The plurality of memory devices 1<A:J> or the volatile memory devices 144 included in the controller 130 as an operating memory stores data for driving the memory system 110 and the controller 130. More specifically, the plurality of memory devices 1<A:J> or the volatile memory devices 144 included in the controller 130 as the operating memory stores data necessary for control when the controller 130 controls the external memory device 150 or 1<A:J> in response to a request from the host 102.

The processor 134 may control the overall operations of the memory system 110. For example, the processor 134 can control a program operation or a read operation of the memory device 1<A:J> or 150 in response to a write request or a read request entered from the host 102.

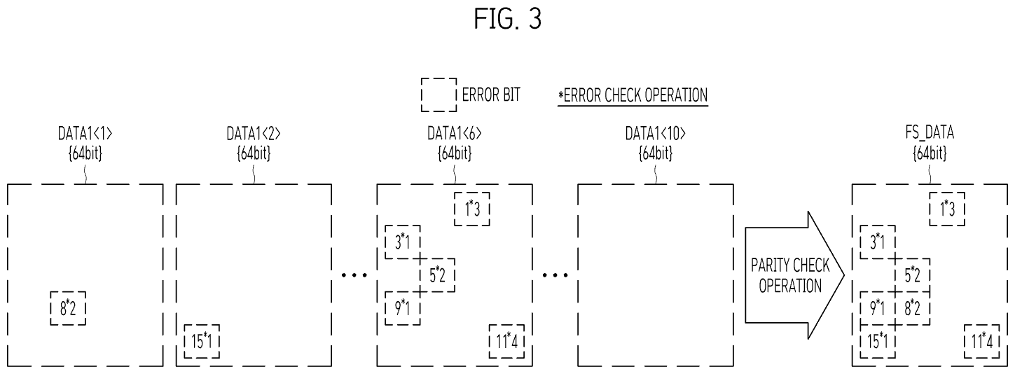

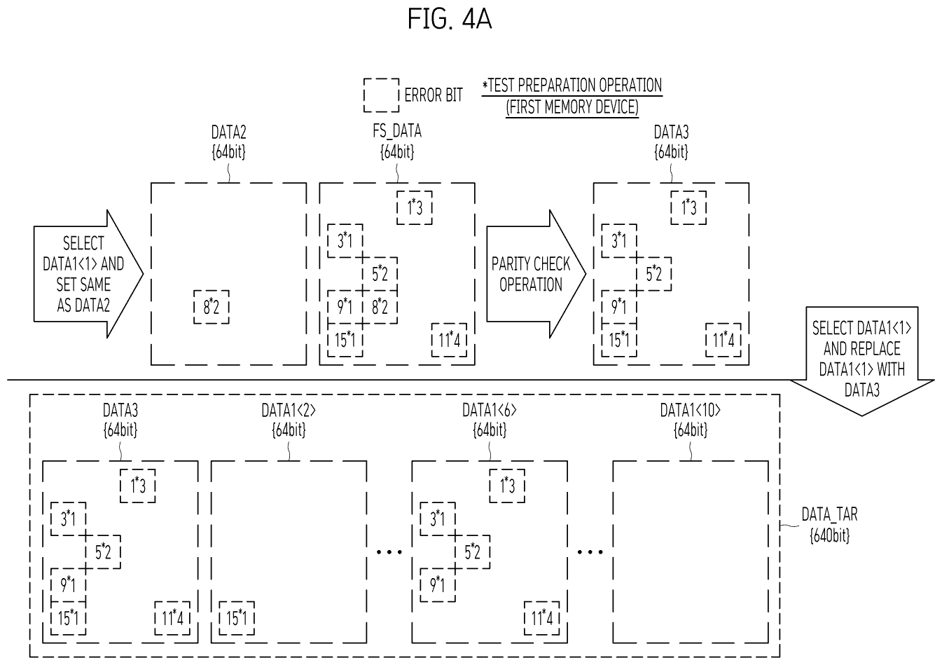

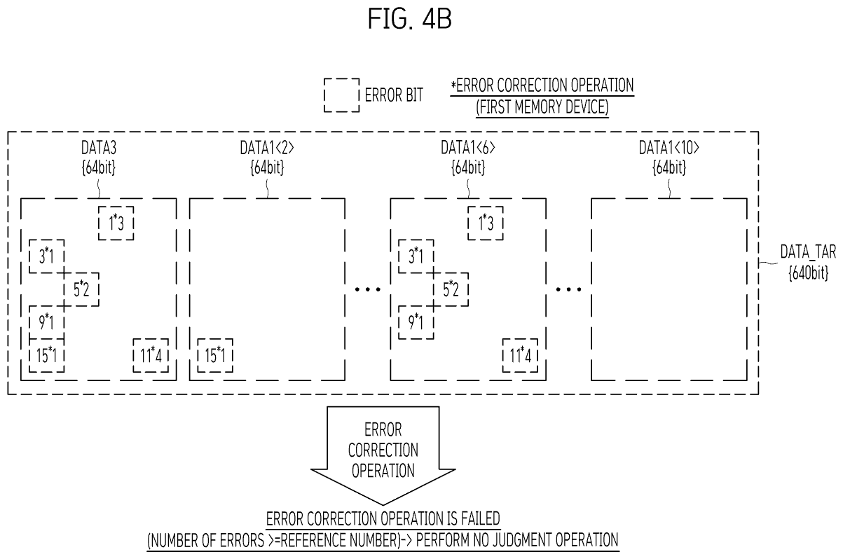

According to an embodiment, the processor 134 may execute firmware to control the program operation or the read operation in the memory system 110. Herein, the firmware may be referred to as a flash translation layer (FTL). An example of the FTL will be described in detail, referring to FIGS. 3 and 4. According to an embodiment, the processor 134 may be implemented with a microprocessor, a central processing unit (CPU), or the like.

According to an embodiment, the memory system 110 may be implemented with at least one multi-core processor. The multi-core processor is a type of circuit or chip in which two or more cores, which are considered distinct processing regions, are integrated. For example, when a plurality of cores in the multi-core processor drive or execute a plurality of flash translation layers (FTLs) independently, a data input/output speed (or performance) of the memory system 110 may be improved. According to an embodiment, the data input/output (I/O) operations in the memory system 110 may be independently performed through different cores in the multi-core processor.

The processor 134 controls the entire operations of the memory system 110. In particular, the processor 134 controls a program operation or a read operation for the memory device 1<A:J> or 150, in response to a write request or a read request from the host 102. The processor 134 drives firmware which is referred to as a flash translation layer (FTL), to control general operations of the memory system 110. The processor 134 may be realized by a microprocessor or a central processing unit (CPU).

For instance, the controller 130 performs an operation requested from the host 102, in the memory device 1<A:J> or 150. That is, the controller 130 performs a command operation corresponding to a command received from the host 102, with the memory device 1<A:J> or 150, through the processor 134 embodied by a microprocessor or a central processing unit (CPU). The controller 130 may perform a foreground operation as a command operation corresponding to a command received from the host 102. For example, the controller 130 may perform a program operation corresponding to a write command, a read operation corresponding to a read command, an erase operation corresponding to an erase command.

The controller 130 may also perform a background operation for the memory device 1<A:J> or 150, through the processor 134 embodied by a microprocessor or a central processing unit (CPU). The background operation for the memory device 1<A:J> or 150 may include an operation of copying data stored in a memory block among the memory blocks 152, 154 and 156 of the memory device 1<A:J> or 150 to another memory block, for example, a garbage collection (GC) operation. The background operation may include an operation of swapping data between one or more of the memory blocks 152, 154 and 156 of the memory device 1<A:J> or 150, for example, a wear leveling (WL) operation, a read reclaim (RR) operation and media scan operation. The background operation may include an operation of storing map data retrieved from the controller 130 in the memory blocks 152, 154 and 156 of the memory device 1<A:J> or 150, for example, a map flush operation. The background operation may include a bad management operation for the memory device 1<A:J> or 150, which may include checking for and processing a bad block among the plurality of memory blocks 152, 154 and 156 in the memory device 1<A:J> or 150.

The fact that the number of the plurality of memory devices 1<A:J> included in the memory module 11 in the drawing is 10 is merely an example, and actually, a smaller or larger number of memory devices can be included as one memory module 11. However, for the convenience, the following description is given based on that the number of the plurality of memory devices 1<A:J> is 10.

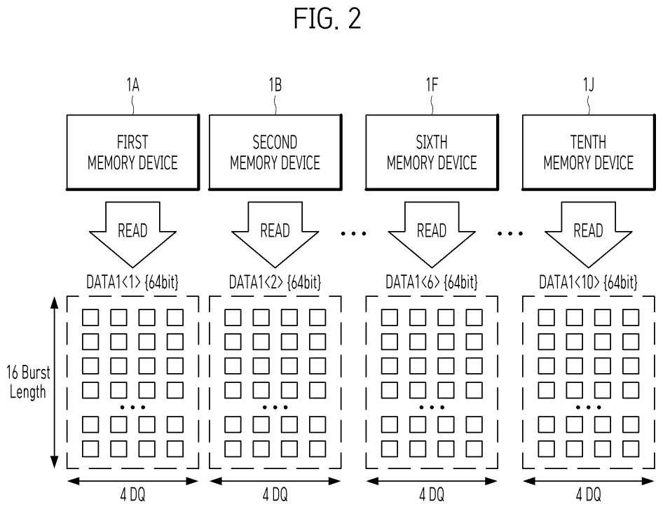

FIG. 2 is a diagram for describing data read from the plurality of memory devices included in the memory system in accordance with the embodiment of the present disclosure.

Referring to FIG. 2, the memory system 110 in accordance with the embodiment of the present disclosure reads 10 first data pieces DATA1<1:10> respectively from the first to tenth memory devices 1<A:J>.

Specifically, each of the first to tenth memory devices 1<A:J> reads and outputs a total of 64 bits as the first data piece (i.e., one among the first data pieces DATA1<1:10>) having a burst length of 16 at once through four data pads DQ. That is, the first to tenth memory devices 1<A:J> read and output a total of 640 bits of first data pieces DATA1<1:10> at once.

It can be seen that in the drawing, the 10 first data pieces DATA1<1:10> read and output respectively from the first to tenth memory devices 1<A:J> is illustrated in a matrix form. That is, in the drawing, 64-bit data included in each of the 10 first data pieces DATA1<1:10>, that is, 16 pieces of bit data are illustrated in four columns with dot lines.

More specifically, the 10 first data pieces DATA1<1:10> read and output respectively from the first to tenth memory devices 1<A:J> each includes target data requested to be read and an error correction code. The error correction code is data written together with the target data by being generated through an error correction encoding operation when the target data is written to the first to tenth memory devices 1<A:J>.

FIG. 3 is a diagram for describing an error check operation in the error correction process performed by the memory system in accordance with the embodiment of the present disclosure.

Referring to FIG. 3, the error check operation 14 is performed in the error correction process performed by the memory system in accordance with the embodiment of the present disclosure.

First, in FIG. 2 described above, an error bit occurs at an arbitrary location that is not known in advance among the 10 first data pieces DATA1<1:10> read respectively from the first to tenth memory devices 1<A:J>.

In such a case, in order to check whether an error has occurred in the 10 first data pieces DATA1<1:10>, the error correction device 13 included in the memory system 110 generates an error sum data piece FS_DATA by performing a parity check operation on the 10 first data pieces DATA1<1:10> by using an error correction code being a part of the 10 first data pieces DATA1<1:10>.

Specifically, as shown in the drawing, an error occurs in bit data 8*2 of a second data pad, the bit data 8*2 being output in the eighth order of the 16 burst length in the first piece DATA1> of the 10 first data pieces DATA1<1:10>.

As also shown in the drawing, an error occurs in bit data 15*1 of a first data pad, the bit data 15*1 being output in the fifteenth order of the 16 burst length in the second piece DATA1<2> of the 10 first data pieces DATA1<1:10>.

As further shown in the drawing, errors occur in bit data 3*1 and 9*1 of the first data pad, the bit data 3*1 and 9*1 being output in the third and ninth order of the 16 burst length in the sixth piece DATA1<6> of the 10 first data pieces DATA1<1:10>, bit data 5*2 of the second data pad, the bit data 5*2 being output in the second order thereof, bit data 1*3 of a third data pad, the bit data 1*3 being output in the first order thereof, and bit data 11*4 of a fourth data pad, the bit data 11*4 being output in the eleventh order thereof.

In this way, in the drawing error bits occur only in the first piece DATA1<1>, the second piece DATA1<2>, and the sixth piece DATA1<6> among the 10 first data pieces DATA1<1:10>, and no error bits occur in the rest. In particular, the error bits are concentrated in the sixth piece DATA1<6> among the 10 first data pieces DATA1<1:10>. That is, a SDDC error state is caused by the error bits being concentrated in the first data piece DATA1<6> read and output from the sixth memory device 1F being one of the first to tenth memory devices 1<A:J>.

On the other hand, the error correction device 13 generates the error sum data piece FS_DATA by adding up all error bits generated from the 10 first data pieces DATA1<1:10> through a parity check operation. That is, the error correction device 13 generates the error sum data piece FS_DATA by performing an exclusive OR operation on the error bits generated from the first piece DATA1<1>, the second piece DATA1<2>, and the sixth piece DATA1<6> among the 10 first data pieces DATA1<1:10>. Accordingly, errors have occurred in the bit data 3*1, 9*1, and 15*1 of the first data pad, the bit data 3*1, 9*1, and 15*1 being output in the third, ninth, and fifteenth orders of the 16 burst length in 64 bits distinguished by the error sum data piece FS_DATA, the bit data 5*2 and 8*2 of the second data pad, the bit data 5*2 and 8*2 being output in the fifth and eighth orders thereof, the bit data 1*3 of the third data pad, the bit data 1*3 being output in the first order thereof, and the bit data 11*4 of the fourth data pad, the bit data 11*4 being output in the eleventh order thereof.

In such a case, in only the parity check operation of generating the error sum data piece FS_DATA, it is possible to determine whether an error has occurred in all 10 memory devices 1<A:J> and an entire error pattern that has occurred, but it is not possible to determine how many error bits are included in all 10 memory devices 1<A:J> and at which location the error bits occurred.

Accordingly, the error correction device 13 checks how many error bits are included in all 10 first data pieces DATA1<1:10> and the locations of the generated error bits through a first initial determination operation of further performing an error detection operation on the 10 first data pieces DATA1<1:10> separately from the operation of generating the error sum data piece FS_DATA, and determines whether the error correction process is successful based on the check result. In such a case, the error correction device 13 performs the error detection operation on the 10 first data pieces DATA1<1:10> by using an error correction code being a part of the 10 first data pieces DATA1<1:10>.

That is, the error correction device 13 performs the error check operation 14 in the error correction process, and then selectively performs a first initial determination operation of checking how many error bits are included in all of the first to tenth memory devices 1<A:J> and the locations of the generated error bits through the error detection operation. In addition, the error correction device 13 selects whether to perform the remaining operations following the error check operation 14 in the error correction process, that is, the test preparation operation 15, the error correction operation 16, the judgment operation 17, and the determination operation 18, according to the result of performing the first initial determination operation.

According to an embodiment, when the number of error bits generated in all of the first to tenth memory devices 1<A:J> through the error detection operation is less than a set number and the locations of the generated error bits are not concentrated in a specific memory device, the error correction device 13 may not perform the remaining operations in the error correction process, that is, the test preparation operation 15, the error correction operation 16, the judgment operation 17, and the determination operation 18, after performing the error check operation 14. That is, the error correction device 13 may determine the error correction process to be successful and output the 10 first data pieces DATA1<1:10> as read data as they are. In the case illustrated in the drawing, the set number may be three, but this is merely an embodiment and may be changed to any other value.

According to another embodiment, when the number of error bits generated in all of the first to tenth memory devices 1<A:J> through the error detection operation is less than the set number but the locations of the generated error bits are concentrated in the specific memory device, the error correction device 13 performs the remaining operations in the error correction process, that is, the test preparation operation 15, the error correction operation 16, the judgment operation 17, and the determination operation 18, after performing the error check operation 14.

The error detection operation is an error check operation using any of the Bose-Chaudhuri-Hocquenghem (BCH) code and the Reed-Solomon (RS) code, and a cyclic redundancy check (CRC), but error detection operation is not limited thereto.

FIGS. 4A and 4B are diagrams for describing the test preparation operation and the error correction operation in the error correction process performed by the memory system in accordance with the embodiment of the present disclosure.

Referring to FIGS. 4A and 4B, the test preparation operation 15 and the error correction operation 16 in the error correction process performed by the memory system in accordance with the embodiment of the present disclosure can be seen. In particular, an operation of selecting the first memory device 1A of the first to tenth memory devices 1<A:J> as a target memory device and performing the test preparation operation 15 and the error correction operation 16 can be seen.

Specifically, referring to FIG. 4A, the error correction device 13 sets, as second data piece DATA2, the first piece DATA1<1>, which is from the 10 first data pieces DATA1<1:10> read from the first memory device 1A. In addition, the error correction device 13 generates a third data piece DATA3 by performing a parity check operation between the second data piece DATA2 and the error sum data piece FS_DATA.

First, as described with reference to FIGS. 2 and 3, the 64 bits of first piece DATA1<1>, which is from the 10 first data pieces DATA1<1:10> and read from the first memory device 1A and is set as the second data piece DATA2, may have an error in the bit data 8*2 of the second data pad, the bit data 8*2 being output in the eighth order of the 16 burst length. In addition, in the 64 bit of data distinguished as the error sum data piece FS_DATA, errors have occurred in the bit data 3*1, 9*1, and 15*1 of the first data pad, the bit data 3*1, 9*1, and 15*1 being output in the third, ninth, and fifteenth orders of the 16 burst length, the bit data 5*2 and 8*2 of the second data pad, the bit data 5*2 and 8*2 being output in the fifth and eighth orders thereof, the bit data 1*3 of the third data pad, the bit data 1*3 being output in the first order thereof, and the bit data 11*4 of the fourth data pad, the bit data 11*4 being output in the eleventh order thereof.

When a parity check operation is performed between the second data piece DATA2 and the error sum data piece FS_DATA, error bits overlapping each other are deleted, and only the other error bits remain. Accordingly, in the 64 bit of data set as the third data piece DATA3, errors have occurred in the bit data 3*1, 9*1, and 15*1 of the first data pad, the bit data 3*1, 9*1, and 15*1 being output in the third, ninth, and fifteenth orders of the 16 burst length, the bit data 5*2 of the second data pad, the bit data 5*2 being output in the fifth order thereof, the bit data 1*3 of the third data pad, the bit data 1*3 being output in the first order thereof, and the bit data 11*4 of the fourth data pad, the bit data 11*4 being output in the eleventh order thereof. That is, the third data piece DATA3 is generated with only the other error bits 3*1, 9*1, 15*1, 5*2, 1*3, and 11*4, excluding bit data overlapping the second data piece DATA2, that is, the bit data 8*2 of the second data pad, the bit data 8*2 being output in the eighth order of the 16 burst length, among the error bits included in the error sum data piece FS_DATA.

After generating the third data piece DATA3, the error correction device 13 generates test data DATA_TAR by replacing, with the third data piece DATA3, the second data piece DATA2, which is the first piece DATA1<1> among the 10 first data pieces DATA1<1:10>.

In summary, the error correction device 13 sets as the second data piece DATA2 the first piece DATA1<1> of the 10 number of first data pieces DATA1<1:10>, generates the third data piece DATA3 by performing a parity bit operation between the second data piece DATA2 and the error sum data piece FS_DATA, and then generates the test data DATA_TAR by replacing with the third data piece DATA3 the second data piece DATA2, which is the first piece DATA1<1> of the 10 first data pieces DATA1<1:10>.

In such a case, the 10 first data pieces DATA1<1:10> are 640 bits, and the first piece DATA1<1> set as the second data piece DATA2 among them is 64 bits. In addition, the error correction device 13 generates the 640-bit test data DATA_TAR by replacing the 64-bit second data piece DATA2 among the 10 first data pieces DATA1<1:10> of 640 bits with the 64-bit third data piece DATA3. Accordingly, when the error sum data piece FS_DATA is compared with the test data DATA_TAR, only the 64 bits of data replaced from the second data piece DATA2 to the third data piece DATA3 are different, and the other 576 bits of data are completely identical.

After the first memory device 1A is selected as the target memory device, the test data DATA_TAR generated by performing the test preparation operation 15 includes all error bits 3*1, 9*1, 15*1, 5*2, 1*3, and 11*4 included in the third data piece DATA3 and the error bits 15*1, 3*1, 9*1, 5*2, 1*3, and 11*4 included in the second and sixth pieces DATA1<2,6> among the 10 first data pieces DATA1<1:10>. That is, after the first memory device 1A is selected as the target memory device, the test data DATA_TAR generated by performing the test preparation operation 15 includes 12 error bits, which is a larger number than 7 being the number of error bits included in the 10 first data pieces DATA1<1:10> before the test preparation operation 15 is performed.

Referring to FIG. 4B, the error correction device 13 performs the error correction operation 16 on the test data DATA_TAR generated by performing the test preparation operation 15 after the first memory device 1A is selected as the target memory device. In such a case, as described with reference to FIG. 4A, the test data DATA_TAR includes 12 error bits that may be a larger number than the number for determining whether the error correction operation is successful or failed. Accordingly, in the result of performing the error correction operation 16 by the error correction device 13 on the test data DATA_TAR including 12 error bits, the error correction is determined to be failed. In this way, since the error correction operation 16 has been determined to be failed, the error correction device 13 is not able to generate correction data piece (not illustrated) generated as a result of the error correction operation 16. Accordingly, the error correction device 13 may not perform the judgment operation 17 being an operation performed on the correction data piece during the error correction process.

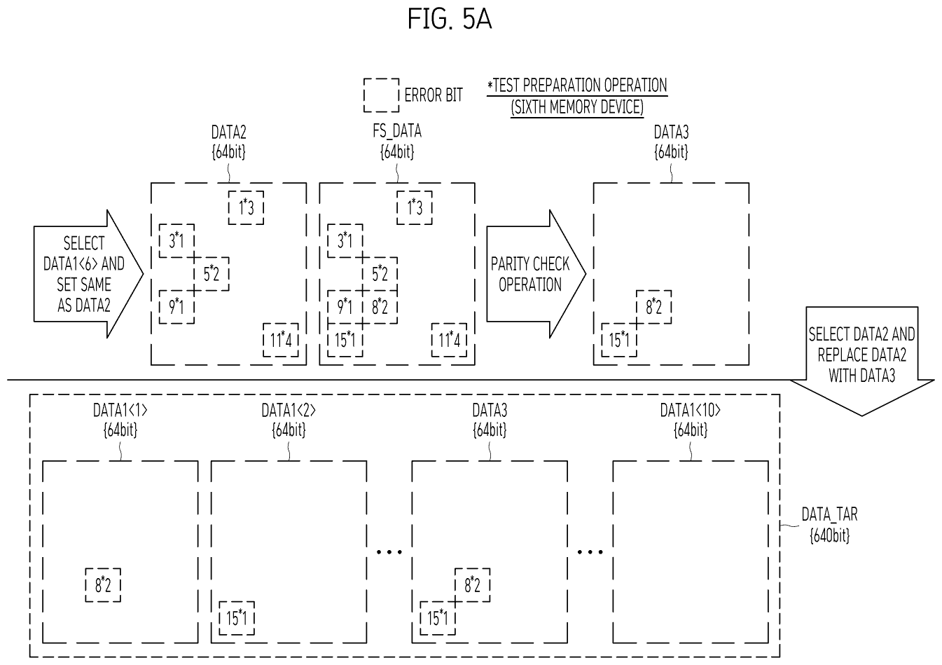

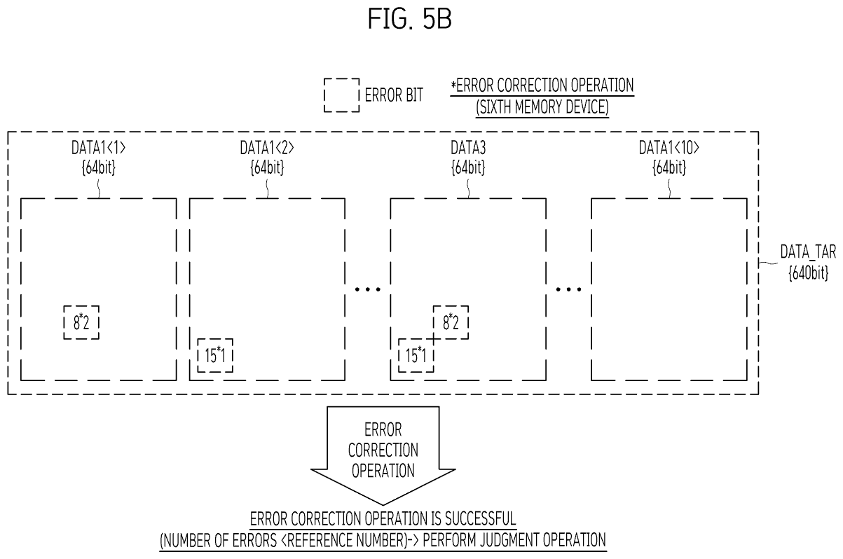

FIGS. 5A and 5B are diagrams for describing another test preparation operation and error correction operation in the error correction process performed by the memory system in accordance with the embodiment of the present disclosure.

Referring to FIGS. 5A and 5B, another test preparation operation 15 and error correction operation 16 in the error correction process performed by the memory system in accordance with the embodiment of the present disclosure can be seen. In particular, an operation of selecting the sixth memory device 1F of the first to tenth memory devices 1<A:J> as a target memory device and performing the test preparation operation 15 and the error correction operation 16 can be seen.

Specifically, referring to FIG. 5A, the error correction device 13 sets, as second data piece DATA2, the sixth piece DATA1<6>, which is from the 10 first data pieces DATA1<1:10> read from the sixth memory device 1F. In addition, the error correction device 13 generates third data piece DATA3 by performing a parity check operation between the second data piece DATA2 and the error sum data piece FS_DATA.

First, as described with reference to FIGS. 2 and 3, the 64 bits of sixth piece DATA1<6>, which is from the 10 first data pieces DATA1<1:10> read from the sixth memory device 1F and is set as the second data piece DATA2, may have errors in the bit data 3*1 and 9*1 of the first data pad, the bit data 3*1 and 9*1 being output in the third and ninth order of the 16 burst length, the bit data 5*2 of the second data pad, the bit data 5*2 being output in the fifth order thereof, the bit data 1*3 of the third data pad, the bit data 1*3 being output in the first order thereof, and the bit data 11*4 of the fourth data pad, the bit data 11*4 being output in the eleventh order thereof. In addition, in the 64 bit of data distinguished as the error sum data piece FS_DATA, errors have occurred in the bit data 3*1, 9*1, and 15*1 of the first data pad, the bit data 3*1, 9*1, and 15*1 being output in the third, ninth, and fifteenth orders of the 16 burst length, the bit data 5*2 and 8*2 of the second data pad, the bit data 5*2 and 8*2 being output in the fifth and eighth orders thereof, the bit data 1*3 of the third data pad, the bit data 1*3 being output in the first order thereof, and the bit data 11*4 of the fourth data pad, the bit data 11*4 being output in the eleventh order thereof.

When a parity check operation is performed between the second data piece DATA2 and the error sum data piece FS_DATA, error bits overlapping each other are deleted, only the other error bits remain. Accordingly, in the 64 bits of data set as the third data piece DATA3, errors have occurred in the bit data 15*1 of the first data pad, the bit data 15*1 being output in the fifteenth order of the 16 burst length and the bit data 8*2 of the second data pad, the bit data 8*2 being output in the eighth order thereof. That is, the third data piece DATA3 is generated with only the other error bits 15*1 and 8*2, excluding bit data overlapping the second data piece DATA2, that is, the bit data 3*1 and 9*1 of the first data pad, the bit data 3*1 and 9*1 being output in the third and ninth orders of the 16 burst length, the bit data 5*2 of the second data pad, the bit data 5*2 being output in the fifth order thereof, the bit data 1*3 of the third data pad, the bit data 1*3 being output in the first order thereof, and the bit data 11*4 of the fourth data pad, the bit data 11*4 being output in the eleventh order thereof, among the error bits included in the error sum data piece FS_DATA.

After generating the third data piece DATA3, the error correction device 13 replaces the second data piece DATA2, which is the sixth piece DATA1<6> among the 10 first data pieces DATA1<1:10>, with the third data piece DATA3 and generates test data DATA_TAR.

In summary, the error correction device 13 sets the sixth piece DATA1<6> of the 10 first data pieces DATA1<1:10> as the second data piece DATA2, generates the third data piece DATA3 by performing a parity bit operation between the second data piece DATA2 and the error sum data piece FS_DATA, and then generates the test data DATA_TAR by replacing the second data piece DATA2, which is the sixth piece DATA1<6> of the 10 first data pieces DATA1<1:10>, with the third data piece DATA3.

In such a case, the 10 first data pieces DATA1<1:10> are 640 bits, and the sixth piece DATA1<6> set as the second data piece DATA2 among them is 64 bits. In addition, the error correction device 13 generates the 640-bit test data DATA_TAR by replacing the 64-bit second data piece DATA2 among the 10 first data pieces DATA1<1:10> of 640 bits with the 64-bit third data piece DATA3. Accordingly, when the error sum data piece FS_DATA is compared with the test data DATA_TAR, only the 64 bits of data replaced from the second data piece DATA2 to the third data piece DATA3 are different, and the other 576 bits of data are completely identical.

After the sixth memory device 1F is selected as the target memory device, the test data DATA_TAR generated by performing the test preparation operation 15 includes all error bits 15*1 and 8*2 included in the third data piece DATA3 and the error bits 15*1 and 8*2 included in the first and second data piece DATA1<1,2> of the 10 number of first data pieces DATA1<1:10>. That is, after the sixth memory device 1F is selected as the target memory device, the test data DATA_TAR generated by performing the test preparation operation 15 includes 4 error bits, which is a smaller number than 7 being the number of error bits included in the 10 first data pieces DATA1<1:10> before the test preparation operation 15 is performed.

Referring to FIG. 5B, the error correction device 13 performs the error correction operation 16 on the test data DATA_TAR generated by performing the test preparation operation 15 after the sixth memory device 1F is selected as the target memory device. In such a case, as described with reference to FIG. 5A, the test data DATA_TAR included 4 error bits that may be a smaller number than the number for determining whether the error correction operation is successful or failed. Accordingly, as the result of performing the error correction operation 16 by the error correction device 13 on the test data DATA_TAR including 4 error bits, the error correction is determined to be successful. In this way, since the error correction operation 16 has been determined to be successful, the error correction device 13 is able to generate correction data piece (not illustrated) generated as a result of the error correction operation 16. Accordingly, the error correction device 13 performs the judgment operation 17 being an operation performed on the correction data piece during the error correction process.

In such a case, the judgment operation 17 is an operation of judging whether a miscorrection has occurred in the correction data piece generated by the successful error correction operation 16 on the test data DATA_TAR. That is, although it is confirmed that the error correction operation 16 has been performed on the test data DATA_TAR and the error correction has been successful, a miscorrection in which an error is not actually corrected may occur. The error correction device 13 in accordance with the embodiment of the present disclosure can judge whether a miscorrection has occurred by performing the judgment operation 17 on the correction data piece.

More specifically, the error correction device 13 performs the judgment operation 17 on the correction data piece confirmed to have been successfully error-corrected through the error correction operation 16 in the following order.

First, the error correction device 13 performs a first judgment operation of performing a parity check operation on the correction data piece by using an error correction code and judging, as success, a case in which no error occurs as a result of performing the parity check operation. In such a case, when no miscorrection occurs in the error correction operation 16, no error bit should be generated in the result of performing the parity check operation on the correction data piece.

In addition, the error correction device 13 performs a second judgment operation of judging, as success, a case in which the number of bits in which error correction is successful in the remaining data excluding data corresponding to the target memory device out of the correction data piece is equal to or less than a reference number. For example, in FIGS. 5A and 5B, the test data DATA_TAR includes a total of 4 error bits, and the third data piece DATA3 corresponding to the sixth memory device 1F selected as the target memory device includes 2 error bits. Accordingly, the error correction device 13 performs, as the second judgment operation, an operation of checking whether the 2 error bits, which are included in the remaining data DATA1<1:5,7:10> excluding the 2 error bits included in the third data piece DATA3 corresponding to the target memory device among the 4 error bits included in the test data DATA_TAR, is equal to or less than the reference number. The reference number may be set to a value corresponding to half of the maximum number of error bits that can be successfully corrected in the error correction operation 16. For example, when the maximum number of error bits that can be successfully corrected in the error correction operation 16 is 10, the reference number may be set to 5.

When both the first and second judgment operations are determined to be successful, the error correction device 13 judges that no miscorrection has occurred in the correction data piece.

When either one of the first and second judgment operations is determined to be failed, the error correction device 13 judges that a miscorrection has occurred in the correction data piece.

The error correction device 13 simultaneously performs the first judgment operation and the second judgment operation in parallel or performs one operation first and the other one later.

In summary, as described with reference to FIGS. 4A, 4B, 5A, and 5B, the error correction device 13 selects each of the 10 memory devices 1<A:J> as a target memory device, performs the test preparation operation 15 and the error correction operation 16, and selectively performs the judgment operation 17 according to the results of the test preparation operation 15 and the error correction operation 16.

That is, as described with reference to FIGS. 4A and 4B, the error correction operation 16 is performed on the test data DATA_TAR generated as a result of the test preparation operation 15, but when the error correction operation fails because the test data DATA_TAR includes more than a reference number of error bits, the error correction device 13 may not perform the judgment operation 17.

Conversely, as a result of performing the error correction operation 16 on the test data DATA_TAR generated as a result of the test preparation operation 15 as described with reference to FIGS. 5A and 5B, when the test data DATA_TAR includes error bits less than the reference number and the error correction operation is successful, the error correction device 13 performs the judgment operation 17.

In such a case, the error correction device 13 selects each of the 10 memory devices 1<A:J> as a target memory device one by one in a predetermined order, regardless of whether the judgment operation 17 is performed. Accordingly, the judgment operation 17 may be performed up to ten times and may not be performed even once.

That is, the error correction device 13 may perform the determination operation 18 of selecting each of the 10 memory devices 1<A:J> as a target memory device one by one in a predetermined order, repeatedly performing the test preparation operation 15 and the error correction operation 16 ten times, performing the judgment operation 17 from a minimum 0 times to a maximum ten times as a result of the test preparation operations 15 and the error correction operations 16 repeated ten times, and then determining whether the error correction process is successful or failed according to the number of times the judgment operation 17 has been performed and the result of the performed judgment operation 17 (whether a miscorrection has occurred).

More specifically, when each of the 10 memory devices 1<A:J> is selected as a target memory device, the judgment operation 17 is performed at least twice while the test preparation operation 15 and the error correction operation 16 are being repeated ten times, and it is judged that no miscorrection has occurred only in one of the judgment operations 17 performed at least twice, the error correction device 13 may perform the determination operation 18 of determining that the error correction process is successful.

In addition, when each of the 10 memory devices 1<A:J> is selected as a target memory device, the judgment operation 17 is performed once while the test preparation operation 15 and the error correction operation 16 are being repeated ten times, and when it is judged that no miscorrection has occurred in the judgment operation 17 performed once, the error correction device 13 may perform the determination operation 18 of determining that the error correction process is successful.

In addition, when each of the 10 memory devices 1<A:J> is selected as a target memory device, the judgment operation 17 is performed at least twice while the test preparation operation 15 and the error correction operation 16 are being repeated ten times, and when it is judged that no miscorrection has occurred in all judgment operations 17 performed at least twice, the error correction device 13 may perform an operation of comparing at least two correction data pieces generated in each of the at least two error correction operations 16 corresponding to the judgment operations 17 performed at least twice with each other, and determine whether the error correction process is successful or failed according to the comparison result.

As a result of the comparison, when at least two correction data pieces generated respectively from the at least two error correction operations 16 corresponding to the judgment operations 17 performed at least twice and having no miscorrection have the same value, the error correction device 13 may perform the determination operation 18 of determining that the error correction process is successful.

As a result of the comparison, when at least one piece of data has a different value among the at least two correction data pieces generated respectively from the at least two error correction operations 16 corresponding to the judgment operations 17 performed at least twice and having no miscorrection, the error correction device 13 may perform the determination operation 18 of determining that the error correction process is failed.

In addition, when each of the 10 memory devices 1<A:J> is selected as a target memory device and the judgment operation 17 is not performed even once while the test preparation operation 15 and the error correction operation 16 are being repeated ten times, the error correction device 13 may perform the determination operation 18 of determining that the error correction process is failed.

In addition, when each of the 10 memory devices 1<A:J> is selected as a target memory device, the judgment operation 17 is performed at least once while the test preparation operation 15 and the error correction operation 16 are being repeated ten times, and when it is judged that a miscorrection has occurred in the judgment operations 17 performed at least once, the error correction device 13 may perform the determination operation 18 of determining that the error correction process is failed.

On the other hand, after performing the error check operation 14, the error correction device 13 determines whether the error correction process is successful by performing a second initial determination operation of selecting each of the 10 memory devices 1<A:J> as a target memory device and repeating the test preparation operation 15 and the error detection operation ten times, before performing the operation of selecting each of the 10 memory devices 1<A:J> as a target memory device and repeating the test preparation operation 15 and the error correction operation 16 ten times and the judgment operation 17/the determination operation 18 described with reference to FIGS. 4A, 4B, 5A, and 5B.

That is, the error correction device 13 selectively performs the second initial determination operation of determining whether the error correction process is successful by selecting each of the 10 memory devices 1<A:J> as a target memory device and repeating the test preparation operation 15 and the error detection operation ten times after performing the error check operation 14 in the error correction process.

Specifically, the error correction device 13 generates test data DATA_TAR each time the error correction device 13 selects each of the 10 memory devices 1<A:J> as a target memory device and performs the test preparation operation 15, and then performs the error detection operation on the generated test data DATA_TAR to check the total number of error bits generated and the locations of the error bits generated. In such a case, the error correction device 13 performs the error detection operation on the test data DATA_TAR by using an error correction code being a part of the test data DATA_TAR.

That is, the error correction device 13 checks the total number of error bits and the locations of the error bits generated for each of 10 test data DATA_TAR through 10 test preparation operations 15 and error detection operations.

In addition, when the error correction device 13 performs the error detection operation on each of the 10 pieces of test data DATA_TAR and checks that the total number of error bits generated in at least one result among 10 results checked is less than a set number and the locations of the generated error bits are not concentrated in a specific memory device, the error correction device 13 may not perform the operation of selecting each of the 10 memory devices 1<A:J> as a target memory device and repeating the test preparation operation 15 and the error correction operation 16 ten times and the judgment operation 17/the determination operation 18 described with reference to FIGS. 4A, 4B, 5A, and 5B. That is, the error correction device 13 may determine that the error correction process is successful, and output, as read data, any test data DATA_TAR, in which the total number of error bits generated in the error detection operation is less than the set number and the locations of the generated error bits are not concentrated in a specific memory device, among the 10 pieces of test data DATA_TAR.

In addition, after performing the error check operation 14 in the error correction process, the error correction device 13 performs the first initial determination operation described with reference to FIG. 3 before performing the operation of selecting each of the 10 memory devices 1<A:J> as a target memory device and repeating the test preparation operation 15 and the error correction operation 16 ten times and the judgment operation 17/the determination operation 18 described with reference to FIGS. 4A, 4B, 5A, and 5B, and performs the second initial determination operation when the error correction process is not determined to be successful. Of course, the error correction device 13 may not perform the second initial determination operation even when the error correction process is not determined to be successful by performing the first initial determination operation. In addition, the error correction device 13 may not perform both the first initial determination operation and the second initial determination operation.

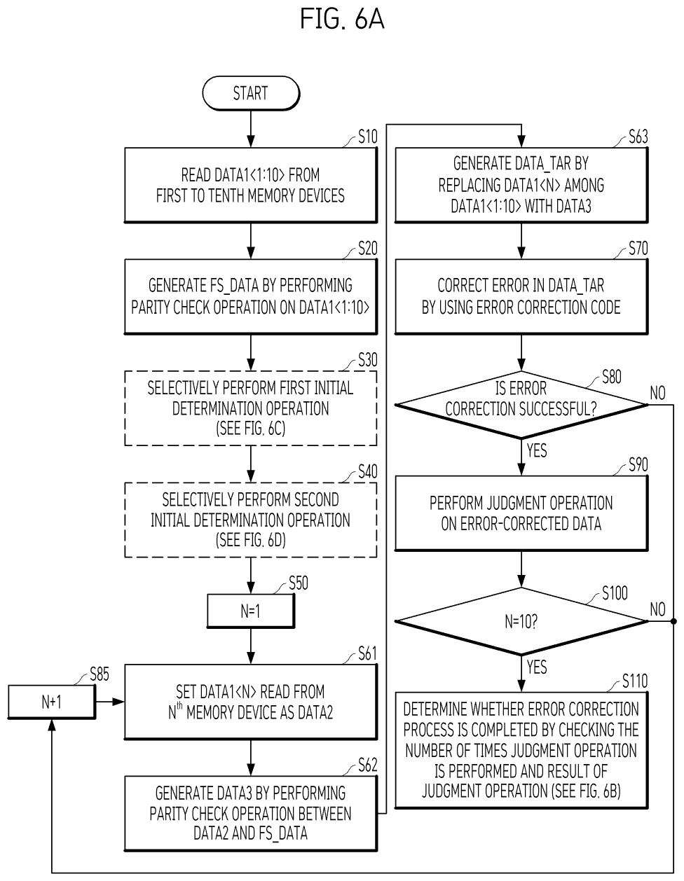

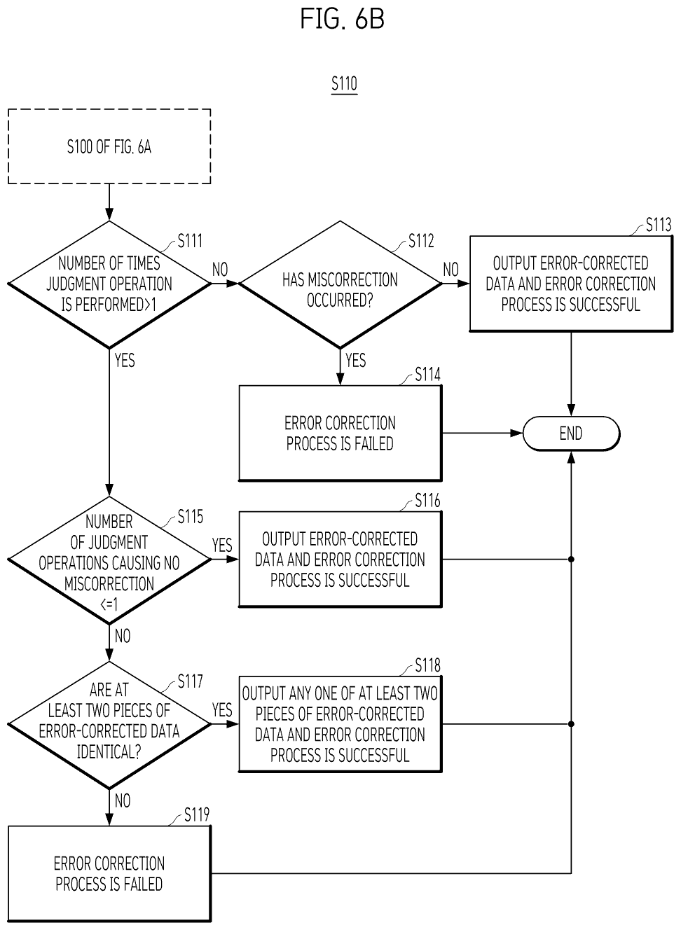

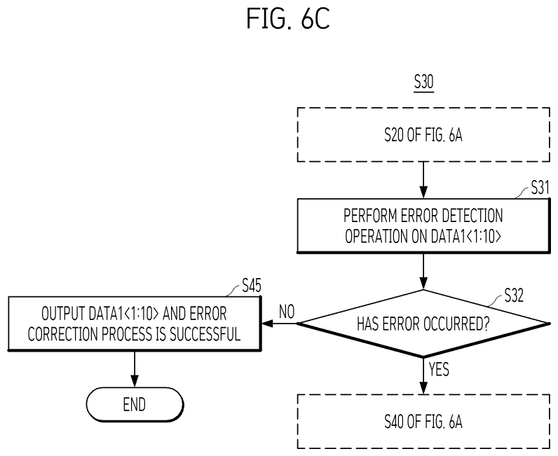

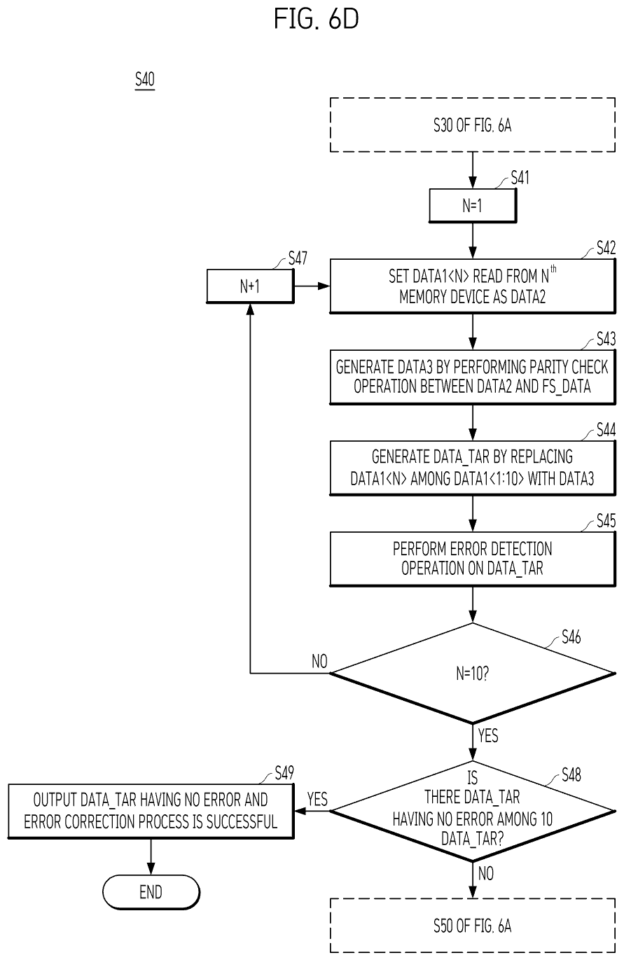

FIGS. 6A to 6D are flowcharts illustrating the order of the error correction process performed by the memory system in accordance with the embodiment of the present disclosure.

Referring to FIGS. 6A to 6D, illustrated is the order in which an error correction process is performed on 10 first data pieces DATA1<1:10> read respectively from the first to tenth memory devices 1<A:J> in the memory system 110 in accordance with the embodiment of the present disclosure.

Referring to FIG. 6A, the 10 first data pieces DATA1<1:10> are read from the first to tenth memory devices 1<A:J> included in the memory system 110 (S10).

The error sum data piece FS_DATA (S20) is generated by performing a parity check operation on the 10 first data pieces DATA1<1:10> read in S10 (S20). That is, the error check operation 14 is performed to generate an error sum data piece FS_DATA by performing the parity check operation on the 10 first data pieces DATA1<1:10> by using an error correction code being a part of the 10 first data pieces DATA1<1:10> read in S10.

After the error sum data piece FS_DATA is generated in S20, the first initial determination operation is selectively performed (S30). Since a specific operation of the first initial determination operation may be referred to FIG. 6C, it is described below.

After the error sum data piece FS_DATA is generated in S20 or the first initial determination operation is performed in S30, the second initial determination operation is selectively performed (S40). Since a specific operation of the second initial determination operation may be referred to FIG. 6D, it is described below.

After the error sum data piece FS_DATA is generated in S20, the first initial determination operation is performed in S30, or the second initial determination operation is performed in S40, each of the 10 memory devices 1<A:J> is selected as a target memory device, the test preparation operation 15 and the error correction operation 16 are repeatedly performed ten times, and the judgment operation 17 is selectively repeated according to the result of the error correction operation 16 (S50, S61, S62, S63, S70, S80, S90, S100, and S85).

Specifically, a variable N for selecting one of the 10 memory devices 1<A:J> as a target memory device is set to 1 (S50). That is, the first memory device 1A of the 10 memory devices 1<A:J> is selected as a target memory device.

First data DATA1<N> read from the target memory device selected in S50 among the first to tenth memory devices 1<A:J> is set as second data piece DATA2 (S61). For example, since N is set to 1 in S50, the first data piece DATA1<1> read from the first memory device 1A may be set as the second data piece DATA2.

The third data piece DATA3 is generated by performing a parity check operation between the second data piece DATA2 set in S61 and the error sum data piece FS_DATA generated in S20 (S62).

Test data DATA_TAR is generated by replacing N^{th} first data DATA1<N> among the 10 first data pieces DATA1<1:10> with the third data piece DATA3 generated in S62 (S63).

The aforementioned S61 to S63 may correspond to the test preparation operation 15.

An error in the test data DATA_TAR generated in S63 is corrected by using an error correction code (S70). The error correction code is a part of the test data DATA_TAR generated in S63.

The aforementioned S70 may correspond to the error correction operation 16.

It is checked whether the error correction operation for the test data DATA_TAR performed in S70 is successful or failed (S80).

When the error correction operation is failed in S80 (N0 in S80), the Value of N is increased by 1 (S85), and the aforementioned S61, S62, S63, S70, and S80 are repeated.

When the error correction operation is successful in S80 (YES in S80), the judgment operation 17 is performed on a correction data piece generated by the success of the error correction operation in S80 (S90). The judgment operation 17 is an operation for judging whether a miscorrection has occurred in the correction data piece generated by the success of the error correction operation 16 on the test data DATA_TAR, and since the judgment operation 17 has already been described with reference to FIGS. 5A and 5B, a detailed description thereof is omitted.

Regardless of the success/failure of the judgment operation 17 performed in S90, whether the value of N has reached 10 is checked (S100). The reason for checking whether the value of N reaches 10 is because the number of the plurality of memory devices illustrated in the present disclosure is 10 and the value of N is changed by setting it to 1 in S50 and then increasing it by 1 in S85. That is, this is because the method of sequentially increasing the value of N from 1 to 10 selects each of the first to tenth memory devices 1<A:J> as a target memory device one by one. The method of selecting each of the first to tenth memory devices 1<A:J> as a target memory device one by one by using the value of N in the present disclosure is merely an example, and any other method can be actually used.

When N does not reach 10 in S100 (NO in S100), the value of N may be increased by 1 (S85), and then the aforementioned S61, S62, S63, S70, S80, S90, and S100 are repeated.

When N reaches 10 in S100 (YES in S100), the test preparation operation 15 and the error correction operation 16 have been repeated ten times through the aforementioned S50, S61, S62, S63, S70, S80, S90, and S100, and then the determination operation 18 of determining whether the error correction process is successful or failed is performed by checking the number of times the judgment operation 17 selectively performed according to the result of the error correction operation 16 has been actually performed and the result of the judgment operation 17 performed (S110).

Referring to FIG. 6B, it can be seen in what order the determination operation 18 performed in S110 of FIG. 6A is performed.

First, the point in time when S110 of FIG. 6A is performed may be in a point in time when the test preparation operation 15 and the error correction operation 16 have been repeated ten times in S50, S61, S62, S63, S70, S80, S90, and S100 and then the judgment operation 17 has been performed a minimum 0 times and a maximum ten times according to the result of the error correction operation 16.

Accordingly, in FIG. 6B, it is checked whether the number of times the judgment operation 17 is performed exceeds 1 at the point in time when S110 is performed (S111).

When the number of times the judgment operation 17 is performed in S111 does not exceed 1, that is, when the judgment operation 17 is performed only once (NO in S111), it is checked whether a miscorrection has occurred in the judgment operation 17 performed only once (S112).

When the miscorrection has occurred in S112 (YES in S112), it can be determined that the error correction process is failed (S114). When it is determined that the error correction process is failed, information indicating a failure of the error correction process is output instead of read data.

When no miscorrection has occurs in S112 (NO in S112), it is determined that the error correction process is successful, and a correction data piece having no miscorrection is output as the read data (S113).

When the number of times the judgment operation 17 is performed in S11 exceeds 1, that is, the judgment operation 17 is performed at least twice (YES in S111), it is checked whether the number of judgment operations 17 causing no miscorrection among the judgment operations 17 performed at least twice is 1 or less (S115).

When the number of judgment operations 17 causing no miscorrection among the judgment operations 17 performed at least twice in S115 is 1 or less (YES in S115), it is determined that the error correction process is successful, and a correction data piece corresponding to one judgment operation 17 causing no miscorrection among the judgment operations 17 performed at least twice is output as read data (S116).

When the number of judgment operations 17 causing no miscorrection among the judgment operations 17 performed at least twice in S15 exceeds 1 (NO in S115), that is, it is checked whether at least two correction data pieces corresponding to at least two judgment operations 17 causing no miscorrection are identical (S117).

When the at least two correction data pieces corresponding to the at least two judgment operations 17 causing no miscorrection are identical in S117 (YES in S117), it is determined that the error correction process is successful, and any of the at least two correction data pieces corresponding to the at least two judgment operations 17 causing no miscorrection is output as read data (S118).

When the at least two correction data pieces corresponding to the at least two judgment operations 17 causing no miscorrection are not identical in S117 (NO of 117), it is determined that the error correction process is failed (S119). When it is determined that the error correction process is failed, information indicating a failure of the error correction process is output instead of the read data.

Referring to FIG. 6C, when the error sum data piece FS_DATA is generated in S20 of FIG. 6A and then the first initial determination operation is performed, it can be seen in what order the first initial determination operation is performed.

First, when the first initial determination operation is started in S30, an error detection operation may be performed on the 10 first data pieces DATA1<1:10> separately from generating the error sum data piece FS_DATA in S20 of FIG. 6A (S31). The error detection operation is performed using the error correction code being a part of the 10 first data pieces DATA1<1:10>.

It is checked whether an error has occurred in the error detection operation performed in S31 (S32).

When no error has occurred in S32 (NO in S32), the error correction process is determined to be successful, and the 10 number of first data pieces DATA1<1:10> are output as read data as they are (S45).

When an error has occurred in S32 (YES in S32), the remaining operations of the error correction process are continuously performed. That is, S40 following S30 of FIG. 6A is performed.

Referring to FIG. 6D, when the second initial determination operation is performed after the error sum data piece FS_DATA is generated in S20 or the first initial determination operation is started in S30, it can be seen in what order the second initial determination operation is performed.

First, when the second initial determination operation is started in S40, the variable N for selecting one of the ten memory devices 1<A:J> as a target memory device is set to 1 (S41). That is, the first memory device 1A of the ten memory devices 1<A:J> is selected as the target memory device.

First data DATA1<N> read from the target memory device selected in S41 among the first to tenth memory devices 1<A:J> is set as a second data piece DATA2 (S42). For example, since N is set to 1 in S41, the first data piece DATA1<1> read from the first memory device 1A may be set as the second data piece DATA2.

The third data piece DATA3 is generated by performing a parity check operation between the second data piece DATA2 set in S42 and the error sum data piece FS_DATA generated in S20 (S43).

Test data DATA_TAR is generated by replacing N^{th} first data DATA1<N> among the 10 first data pieces DATA1<1:10> with the third data piece DATA3 generated in S43 (S44).

The above-described S42 to S44 may correspond to the test preparation operation 15.

An error detection operation is performed on the test data DATA_TAR generated in S44 (S45). The error detection operation is performed using an error correction code being a part of the test data DATA_TAR.

Regardless of the result of the error detection operation in S45, that is, regardless of whether an error has occurred in the test data DATA_TAR, it is checked whether the value of N has reached 10 (S46).

When N is not 10 in S46 (NO in S46), the value of N is increased by 1 (S47), and then the aforementioned S42 to S46 are repeated. The reason for checking whether the value of N reaches 10 is because the number of the plurality of memory devices illustrated in the present disclosure is 10 and the value of N is changed by setting it to 1 in S41 and then increasing it by 1 in S47. That is, this is because the method of sequentially increasing the value of N from 1 to 10 selects each of the first to tenth memory devices 1<A:J> as a target memory device one by one. The method of selecting each of the first to tenth memory devices 1<A:J> as a target memory device one by one by using the value of N in the present disclosure is merely an example, and any other method can be actually used.

A case in which N is 10 in S46 (YES in S46) may be in a state in which each of the ten memory devices 1<A:J> has been selected as a target memory device and the test preparation operation 15 and error detection operation have been repeated ten times. That is, it may be in a state in which the error detection operation has been performed on each of the ten test data DATA_TAR.

It is checked whether test data DATA_TAR having no error is present as results of the error detection operation performed on each of the ten test data DATA_TAR (S48). That is, it is checked whether at least one result, in which the total number of generated error bits is less than a set number and the locations of the generated error bits are not concentrated in a specific memory device, is present among the results of the error detection operation performed on each of the 10 test data DATA_TAR in S48.

When there is the test data DATA_TAR having no error in S48 (YES in S48), it is determined that the error correction process is successful, and the test data DATA_TAR having no error is output as read data (S49).

When there is no test data DATA_TAR having no error in S48 (NO in S48), the remaining operations of the error correction process are continuously performed. That is, S50 following S40 of FIG. 6A is performed.

The concepts of the present disclosure described above is not limited by the aforementioned embodiments and the accompanying drawings, and it will be apparent to those skilled in the art that various replacements, modifications, and changes can be made without departing from the technical scope of the present disclosure. Furthermore, the embodiments may be combined to form additional embodiments.

What is claimed is:

1. An error correction method of a memory system comprising a plurality of memory devices each storing data and an error correction code, the method comprising:
an error check operation of generating an error sum data piece by performing a parity check operation on a plurality of first data pieces read from the respective memory devices by using the error correction code;
a test preparation operation of generating, according to a result of the error check operation, a third data piece by performing a parity check operation between the error sum data piece and a second data piece, which is one among the plurality of first data pieces and read from a target memory device selected from among the plurality of memory devices, to generate test data by replacing the second data piece with the third data piece;
an error correction operation of generating a correction data piece by correcting an error in the test data by using the error correction code;
a judgment operation of judging whether a miscorrection has occurred in the correction data piece when the error correction operation is successful; and
a determination operation of determining, as a result of repeating the test preparation operation, the error correction operation and the judgement operation on the respective first data pieces, whether the error correction method is successful or failed according to a number of times the judgment operation is performed and results of the judgment operation.

2. The error correction method of claim 1, wherein the determination operation determines the error correction method as successful when it is judged that no miscorrection has occurred only in the judgment operation performed once among the judgment operations performed at least twice or no miscorrection has occurred in the judgment operation performed only once.

3. The error correction method of claim 2, wherein the determination operation includes when it is judged that no miscorrection has occurred in all judgment operations performed at least twice:
comparing the correction data pieces generated respectively in the error correction operation respectively corresponding to the judgment operations performed at least twice; and
determining, according to a result of the comparing, whether the error correction method is successful or failed.

4. The error correction method of claim 3, wherein the determination operation determines the error correction method as successful when the correction data pieces are the same as each other as the result of the comparing.

5. The error correction method of claim 3, wherein the determination operation determines the error correction method as failed when at least one correction data piece has a value different from other correction data pieces as the result of the comparing.

6. The error correction method of claim 1, wherein the determination operation determines the error correction method as failed when the judgment operation is not performed once or all judgment operations performed at least once judges that a miscorrection has occurred.

7. The error correction method of claim 1, wherein the judgment operation judges that a miscorrection has occurred in the correction data piece:
when a parity check operation fails on the correction data piece by using the error correction code, or
when a number of bits, on which the error correction operation is successful in a remaining portion other than the third data piece within the correction data piece, is greater than a reference number.

8. The error correction method of claim 1, the error check operation includes:
detecting one or more errors from the plurality of first data pieces by using the error correction code; and
determining to perform the test preparation operation, the error correction operation, the judgment operation, and the determination operation based on a number of the detected errors.

9. The error correction method of claim 1, wherein the error check operation includes:
generating the third data piece by performing a parity check operation between the error sum data piece and the second data piece to generate the test data by replacing the second data piece with the third data piece;
detecting one or more errors from the test data by using the error correction code;
repeating the generating and the detecting for the respective first data pieces; and
determining to perform the test preparation operation, the error correction operation, the judgment operation, and the determination operation based on a number of the detected errors as a result of the repeating.

10. The error correction method of claim 1, wherein the error correction code is a product code formed by multiplying a polynomial (Generator polynominal) generated in response to any of a Bose-Chaudhuri-Hocquenghem (BCH) code and a Reed Solomon (RS) code, a polynomial generated in response to a code for parity check, and a polynomial generated in response to a code for cyclic redundancy check (CRC) together.

11. A memory system comprising:
a plurality of memory devices each configured to store data and an error correction code; and
an error correction device configured to perform an error correction method including:
an error check operation of generating error sum data piece by performing a parity check operation on a plurality of first data pieces read from the respective memory devices by using the error correction code,
a test preparation operation of generating, according to a result of the error check operation, third data piece by performing a parity check operation between the error sum data piece and second data piece, which is one among the plurality of first data pieces and read from a target memory device selected from among the plurality of memory devices, to generate test data by replacing the second data piece with the third data piece,
an error correction operation of generating a correction data piece by correcting an error in the test data by using the error correction code,
a judgment operation of judging whether a miscorrection has occurred in the correction data piece when the error correction operation is successful, and
a determination operation of determining, as a result of repeating the test preparation operation, the error correction operation and the judgement operation on the respective first data pieces, whether the error correction method is successful or failed according to a number of times the judgment operation is performed and results of the judgment operation.

12. The memory system of claim 11, wherein the error correction device performs the determination operation by determining the error correction method as successful when it is judged that no miscorrection has occurred only in the judgment operation performed once among the judgment operations performed at least twice or no miscorrection has occurred in the judgment operation performed only once.

13. The memory system of claim 12, wherein the determination operation includes when it is judged that no miscorrection has occurred in all judgment operations performed at least twice:
comparing the correction data pieces generated respectively in the error correction operations respectively corresponding to the judgment operations, and
determining, according to a result of the comparing, whether the error correction method is successful or failed.

14. The memory system of claim 13, wherein the error correction device performs the determination operation by determining the error correction method as successful when the correction data pieces are the same as each other as the result of the comparing.

15. The memory system of claim 13, wherein the error correction device performs the determination operation by determining the error correction method as failed when at least one correction data piece has a value different from other correction data pieces as the result of the comparing.

16. The memory system of claim 11, wherein the error correction device performs the determination operation by determining the error correction method as failed when the judgment operation is not performed once or all judgment operations performed at least once judges that a miscorrection has occurred.

17. The memory system of claim 11, wherein the error correction device performs the judgment operation by judging that a miscorrection has occurred in the correction data piece:
when a parity check operation fails on the correction data piece by using the error correction code, or
when a number of bits, on which the error correction operation is successful in a remaining portion other than the third data piece within the correction data piece, is greater than a reference number.

18. The memory system of claim 11, wherein the error check operation includes:
detecting one or more errors from the plurality of first data pieces by using the error correction code, and
determining to perform the test preparation operation, the error correction operation, the judgment operation, and the determination operation based on a number of the detected errors.

19. The memory system of claim 11, wherein the error check operation includes:
generating the third data piece by performing a parity check operation between the error sum data piece and the second data piece to generate the test data by replacing the second data piece with the third data piece,
detecting one or more errors from the test data by using the error correction code,
repeating the generating and the detecting for the respective first data pieces, and
determining to perform the test preparation operation, the error correction operation, the judgment operation, and the determination operation based on a number of the detected errors as a result of the repeating.

20. The memory system of claim 11, wherein the error correction code is a product code formed by multiplying a polynomial (Generator polynominal) generated in response to any of a Bose-Chaudhuri-Hocquenghem (BCH) code and a Reed Solomon (RS) code, a polynomial generated in response to a code for parity check, and a polynomial generated in response to a code for cyclic redundancy check (CRC) together.
